(19) United States
(12) Patent Application Publication
(10) Pub. No.: US 2026/0221953 A1
(43) Pub. Date: Jul. 30, 2026

(54) POLY-PHASE FILTER AND ELECTRONIC APPLIANCE

(71) Applicant: Sharp Semiconductor innovation Corporation, Tenri City (JP)

(72) Inventors: Akira YAMAGUCHI, Tenri City (JP); Shigenari TAGUCHI, Tenri city (JP)

(21) Appl. No.: 19/433,266

(22) Filed: Dec. 26, 2025

(30) Foreign Application Priority Data
Jan. 29, 2025 (JP) 2025-013287

(51) Int. Cl. H03H 7/06; H03H 7/21

(52) U.S. Cl. CPC H03H 7/06; H03H 7/21

(57) ABSTRACT

A poly-phase filter, includes: a first resistive element having an end connected to a first input terminal and an other end connected to a first output terminal; a second resistive element having an end connected to the first input terminal and an other end connected to a second output terminal; a first capacitive element having an end connected to the first input terminal; a second capacitive element having an end connected to an other end of the first capacitive element and an other end connected to the second output terminal; a third resistive element having an end connected to a second input terminal and an other end connected to a third output terminal; a third capacitive element having an end connected to the first input terminal.

### CROSS-REFERENCE TO RELATED APPLICATION

The present application claims priority from Japanese Application JP2025-013287, the content of which is hereby incorporated by reference into this application.

### BACKGROUND OF THE INVENTION

### 1. Field of the Invention

The present invention relates to a poly-phase filter and an electronic appliance.

### 2. Description of the Related Art

A known poly-phase filter generates orthogonal signals (see Patent Document 1). The poly-phase filter includes a resistive element and a capacitive element, and generates signals having a phase difference of 90° at a desired frequency. WO2017/141367 discloses a technique to adjust a variable capacitance in order to correct a phase error between first to fourth outputs.

### SUMMARY OF THE INVENTION

However, the conventional technique described above does not necessarily provide a sufficiently wide range for changing frequency of an input signal.

An aspect of the present invention sets out to provide a poly-phase filter capable of handling an input signal with a wide frequency range and to provide an electronic appliance.

In order to solve the above problem, a poly-phase filter according to an aspect of the present invention includes: a first resistive element having an end connected to a first input terminal and an other end connected to a first output terminal; a second resistive element having an end connected to the first input terminal and an other end connected to a second output terminal; a first capacitive element having an end connected to the first input terminal; a second capacitive element having an end connected to an other end of the first capacitive element and an other end connected to the second output terminal; a third resistive element having an end connected to a second input terminal and an other end connected to a third output terminal; a third capacitive element having an end connected to the first input terminal; a fourth capacitive element having an end connected to an other end of the third capacitive element and an other end connected to the third output terminal; a fourth resistive element having an end connected to the second input terminal and an other end connected to a fourth output terminal; a fifth capacitive element having an end connected to the second input terminal; a sixth capacitive element having an end connected to an other end of the fifth capacitive element and an other end connected to the fourth output terminal; a seventh capacitive element having an end connected to the second input terminal; an eighth capacitive element having an end connected to an other end of the seventh capacitive element and an other end connected to the first output terminal; a ninth capacitor having an end connected to the other end of the first capacitive element; a tenth capacitor having an end connected to the other end of the third capacitive element; an eleventh capacitor having an end connected to the other end of the fifth capacitive element; and a twelfth capacitor having an end connected to the other end of the seventh capacitive element. At least one of: (1a) a capacitance of at least any one or more of the seventh capacitive element, the eighth capacitive element, and the twelfth capacitor; or (1b) a resistance of the first resistive element is variable, at least one of: (2a) a capacitance of at least any one or more of the first capacitive element, the second capacitive element, and the ninth capacitor; or (2b) a resistance of the second resistive element is variable, at least one of: (3a) a capacitance of at least any one or more of the third capacitive element, the fourth capacitive element, and the tenth capacitor; or (3b) a resistance of the third resistive element is variable, and at least one of: (4a) a capacitance of at least any one or more of the fifth capacitive element, the sixth capacitive element, and the eleventh capacitor; or (4b) a resistance of the fourth resistive element is variable.

In order to solve the above problem, a poly-phase filter according to an aspect of the present invention includes: a first resistive element having an end connected to a first input terminal and an other end connected to a first output terminal; a second resistive element having an end connected to the first input terminal and an other end connected to a second output terminal; a first capacitive element having an end connected to the first input terminal; a second capacitive element having an end connected to an other end of the first capacitive element and an other end connected to the second output terminal; a third resistive element having an end connected to a second input terminal and an other end connected to a third output terminal; a third capacitive element having an end connected to the first input terminal; a fourth capacitive element having an end connected to an other end of the third capacitive element and an other end connected to the third output terminal; a fourth resistive element having an end connected to the second input terminal and an other end connected to a fourth output terminal; a fifth capacitive element having an end connected to the second input terminal; a sixth capacitive element having an end connected to an other end of the fifth capacitive element and an other end connected to the fourth output terminal; a seventh capacitive element having an end connected to the second input terminal; an eighth capacitive element having an end connected to an other end of the seventh capacitive element and an other end connected to the first output terminal; a ninth capacitor having an end connected to the other end of the first capacitive element and an other end connected to the other end of the fifth capacitive element; and a tenth capacitor having an end connected to the other end of the third capacitive element and an other end connected to the other end of the seventh capacitive element. At least one of: (1c) a capacitance of at least any one or more of the seventh capacitive element and the eighth capacitive element; or (1b) a resistance of the first resistive element is variable, at least one of: (2a) a capacitance of at least any one or more of the first capacitive element, the second capacitive element, and the ninth capacitor; or (2b) a resistance of the second resistive element is variable, at least one of: (3a) a capacitance of at least any one or more of the third capacitive element, the fourth capacitive element, and the tenth capacitor; or (3b) a resistance of the third resistive element is variable, and at least one of: (4c) a capacitance of at least any one or more of the fifth capacitive element and the sixth capacitive element; or (4b) a resistance of the fourth resistive element is variable.

An aspect of the present invention can provide a poly-phase filter capable of handling an input signal with a wide frequency range and to provide an electronic appliance.

### BRIEF DESCRIPTION OF THE DRAWINGS

FIG. 1 illustrates a circuit diagram showing an example of a poly-phase filter according to a first embodiment of the present invention;

FIG. 2 illustrates a circuit diagram showing a poly-phase filter according to a comparative example of the present invention;

FIG. 3 shows a graph representing characteristics of poly-phase filters;

FIG. 4 shows a graph representing a relationship between capacitance ratios and a frequency magnification of a poly-phase filter;

FIG. 5 illustrates circuit diagrams showing poly-phase filters according to modifications of the first embodiment of the present invention;

FIG. 6 illustrates circuit diagrams showing poly-phase filters according to modifications of the first embodiment of the present invention; and

FIG. 7 illustrates a circuit diagram showing an example of a poly-phase filter according to a second embodiment of the present invention.

### DETAILED DESCRIPTION OF THE INVENTION

### First Embodiment

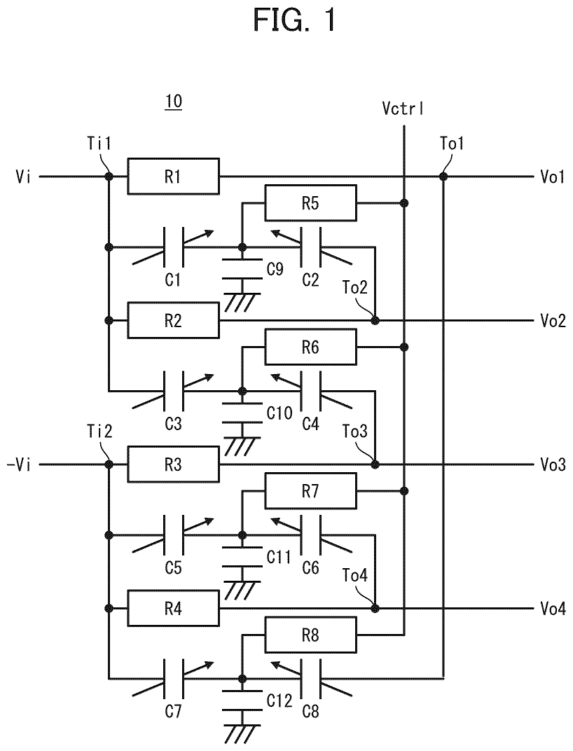

An embodiment of the present invention will be described in detail below. FIG. 1 illustrates a circuit diagram showing an example of a poly-phase filter 10 according to a first embodiment of the present invention. The poly-phase filter 10 can be used for an electronic appliance; that is, for example, a wireless communications appliance that handles wireless communications by orthogonal digital modulation-demodulation (IQ modulation-demodulation). For example, a phase shifter circuit including the poly-phase filter 10 can generate local signals (i.e., signals having a phase difference of 90°) for orthogonal digital modulation-demodulation and change phases of the signals.

The poly-phase filter 10 has: a first input terminal Ti1; a second input terminal Ti2; a first output terminal To1 to a fourth output terminal To4; a first resistive element R1 to an eighth resistive element R8; a first capacitive element C1 to an eighth capacitive element C8; and a ninth capacitor C9 to a twelfth capacitor C12.

Here, the ninth capacitor C9 to the twelfth capacitor C12 (hereinafter also referred to as “capacitors such as the ninth capacitor C9”) are described as “capacitors”. This means that even though the capacitors such as the ninth capacitor C9 may be capacitive elements, the capacitors may also be parasitic capacitances that are not capacitive elements.

The first input terminal Ti1 receives an alternating-current voltage Vi, and the second input terminal Ti2 receives an alternating-current voltage—Vi having an antiphase (a phase difference of 180°) of the alternating-current voltage Vi. The first output terminal To1 to the fourth output terminal To4 respectively output an alternating-current voltage Vo1 to an alternating-current Vo4 adjusted to have the phases shifted in increments of 90°.

Described below will be a configuration of the poly-phase filter 10 according to the first embodiment.

The first resistive element R1 has: an end connected to the first input terminal Ti1; and an other end connected to the first output terminal To1. The second resistive element R2 has: an end connected to the first input terminal Ti1; and an other end connected to the second output terminal To2. The third resistive element R3 has: an end connected to the second input terminal Ti2; and an other end connected to the third output terminal To3. The fourth resistive element R4 has: an end connected to the second input terminal Ti2; and an other end connected to the fourth output terminal To4.

The first capacitive element C1 has: an end connected to the first input terminal Ti1, and the second capacitive element C2 has: an end connected to an other end of the first capacitive element C1; and an other end connected to the second output terminal To2.

The third capacitive element C3 has: an end connected to the first input terminal Ti1, and the fourth capacitive element C4 has: an end connected to an other end of the third capacitive element C3; and an other end connected to the third output terminal To3.

The fifth capacitive element C5 has: an end connected to the second input terminal Ti2, and the sixth capacitive element C6 has: an end connected to an other end of the fifth capacitive element C5; and an other end connected to the fourth output terminal To4.

The seventh capacitive element C7 has: an end connected to the second input terminal Ti2, and the eighth capacitive element C8 has: an end connected to an other end of the seventh capacitive element C7; and an other end connected to the first output terminal To1.

The ninth capacitor C9 has an end connected to the other end of the first capacitive element C1. The tenth capacitor C10 has an end connected to the other end of the third capacitive element C3. The eleventh capacitor C11 has an end connected to the other end of the fifth capacitive element C5. The twelfth capacitor C12 has an end connected to the other end of the seventh capacitive element C7.

The first embodiment may satisfy the conditions below. Note that the details will be described in modifications to be described later.

At least one of: (1a) a capacitance of at least any one or more of the seventh capacitive element C7, the eighth capacitive element C8, and the twelfth capacitor C12; or (1b) a resistance of the first resistive element R1 may be variable. Such a feature successfully adjusts a phase of a signal to be output from the first output terminal To1. Note that, here, the capacitances of the seventh capacitive element C7 and the eighth capacitive element C8 are variable, and the capacitance of the twelfth capacitor C12 and the resistance of the first resistive element R1 are fixed.

Here, the fixed resistance and the fixed capacitance respectively mean a resistance value unique to the first resistive element R1 and a capacitance value unique to the twelfth capacitor C12. The resistance value and the capacitance value are allowed to vary because of such factors as an external environment. In this regard, as to the other resistive elements (e.g., the second resistive element R2 to the eighth resistive element R8) and the other capacitive elements and capacitors (e.g., the first capacitive elements C1 to the eighth capacitive element C8 and the ninth capacitor C9 to the eleventh capacitor C11), the fixed resistance values and the fixed capacitance values may vary because of such factors as an external environment.

At least one of: (2a) a capacitance of at least any one or more of the first capacitive element C1, the second capacitive element C2, and the ninth capacitor C9; or (2b) a resistance of the second resistive element R2 may be variable. Such a feature successfully adjusts a phase of a signal to be output from the second output terminal To2. Note that, here, the capacitances of the first capacitive element C1 and the second capacitive element C2 are variable, and the capacitance of the ninth capacitor C9 and the resistance of the second resistive element R2 are fixed.

At least one of: (3a) a capacitance of at least any one or more of the third capacitive element C3, the fourth capacitive element C4, and the tenth capacitor C10; or (3b) a resistance of the third resistive element R3 may be variable. Such a feature successfully adjusts a phase of a signal to be output from the third output terminal To3. Note that, here, the capacitances of the third capacitive element C3 and the fourth capacitive element C4 are variable, and the capacitance of the tenth capacitor C10 and the resistance of the third resistive element R3 are fixed.

At least one of: (4a) a capacitance of at least any one or more of the fifth capacitive element C5, the sixth capacitive element C6, and the eleventh capacitor C11; or (4b) a resistance of the fourth resistive element R4 may be variable. Such a feature successfully adjusts a phase of a signal to be output from the fourth output terminal To4. Note that, here, the capacitances of the fifth capacitive element C5 and the sixth capacitive element C6 are variable, and the capacitance of the eleventh capacitor C11 and the resistance of the fourth resistive element R4 are fixed.

Other ends of the ninth capacitor C9, the tenth capacitor C10, the eleventh capacitor C11, and the twelfth capacitor C12 are connected to the ground. Such a feature successfully stabilizes resonators each having a corresponding one of the ninth capacitor C9 to the twelfth capacitor C12. For example, the resonator having the ninth capacitor C9 includes: the first capacitive element C1, the second capacitive element C2, the ninth capacitor C9, and the second resistive element R2. The resonator is disposed between the first input terminal Ti1 and the second output terminal To2.

At least any one or more of the first capacitive element C1 to the eighth capacitive element C8 and the ninth capacitor C9 to the twelfth capacitor C12 may be varactor diodes capacitances of which are variable. A varactor diode can be used as a capacitive element a capacitance of which is variable. In the first embodiment, the first capacitive element C1 to the eighth capacitive element C8 are varactor diodes a capacitance of which is variable. The ninth capacitor C9 to the twelfth capacitor C12 have the capacitances fixed.

Here, in order to vary the capacitances of the first capacitive element C1 and the second capacitive element C2, a control voltage Vctrl is applied to the other end of the first capacitive element C1 through the fifth resistive element R5. Likewise, in order to vary the capacitances of the third capacitive element C3 and the fourth capacitive element C4, the control voltage Vctrl is applied to the other end of the third capacitive element C3 through the sixth resistive element R6. In order to vary the capacitances of the fifth capacitive element C5 and the sixth capacitive element C6, the control voltage Vctrl is applied to the other end of the fifth capacitive element C5 through the seventh resistive element R7. In order to vary the capacitances of the seventh capacitive element C7 and the eighth capacitive element C8, the control voltage Vctrl is applied to the other end of the seventh capacitive element C7 through the eighth resistive element R8.

If the capacitances of the first capacitive element C1 to the eighth capacitive element C8 are 2C, the capacitances of the ninth capacitor C9 to the twelfth capacitor C12 are Ca, and the resistances of the first resistive element R1 to the fourth resistive element R4 are R, the first output voltage Vo1 to the fourth output voltage Vo4 of the poly-phase filter 10 are represented as follows by transfer functions.

Vo1=−(4C²Rs−Ca−4C)Vi/A.

Vo2=+(4C²Rs+Ca+4C)Vi/A.

Vo3=+(4C²Rs−Ca−4C)Vi/A.

Vo4=−(4C2Rs+Ca+4C)Vi/A.

A=(2CCa+4C²)Rs+Ca+4c.

A phase difference θ between the first output voltage Vo1 and the second output voltage Vo2 is represented as follows.

θ =tan⁻¹[(8C2Ca+32C³)ωR/B].

B=Ca²+8CCa+16C²−16C⁴R²ω2.

As can be seen, a poly-phase filter according to the first embodiment includes:
a first resistive element having an end connected to a first input terminal and an other end connected to a first output terminal;
a second resistive element having an end connected to the first input terminal and an other end connected to a second output terminal;
a first capacitive element having an end connected to the first input terminal;
a second capacitive element having an end connected to an other end of the first capacitive element and an other end connected to the second output terminal;
a third resistive element having an end connected to a second input terminal and an other end connected to a third output terminal;
a third capacitive element having an end connected to the first input terminal;
a fourth capacitive element having an end connected to an other end of the third capacitive element and an other end connected to the third output terminal;
a fourth resistive element having an end connected to the second input terminal and an other end connected to a fourth output terminal;
a fifth capacitive element having an end connected to the second input terminal;
a sixth capacitive element having an end connected to an other end of the fifth capacitive element and an other end connected to the fourth output terminal;
a seventh capacitive element having an end connected to the second input terminal;
an eighth capacitive element having an end connected to an other end of the seventh capacitive element and an other end connected to the first output terminal;
a ninth capacitor having an end connected to the other end of the first capacitive element;
a tenth capacitor having an end connected to the other end of the third capacitive element;
an eleventh capacitor having an end connected to the other end of the fifth capacitive element; and
a twelfth capacitor having an end connected to the other end of the seventh capacitive element,
wherein at least one of: (1a) a capacitance of at least any one or more of the seventh capacitive element, the eighth capacitive element, and the twelfth capacitor; or (1b) a resistance of the first resistive element is variable,
at least one of: (2a) a capacitance of at least any one or more of the first capacitive element, the second capacitive element, and the ninth capacitor; or (2b) a resistance of the second resistive element is variable,
at least one of: (3a) a capacitance of at least any one or more of the third capacitive element, the fourth capacitive element, and the tenth capacitor; or (3b) a resistance of the third resistive element is variable, and
at least one of: (4a) a capacitance of at least any one or more of the fifth capacitive element, the sixth capacitive element, and the eleventh capacitor; or (4b) a resistance of the fourth resistive element is variable.

Note that, the first resistive element R1, the seventh capacitive element C7, the eighth capacitive element C8, and the twelfth capacitor C12 are connected to the first output terminal To1. The resistance or the capacitance of at least at least any one or more of the resistive element, the capacitive elements, and the capacitor is varied. Such a feature successfully adjusts a phase of a signal to be output from the first output terminal To1.

The second resistive element R2, the first capacitive element C1, the second capacitive element C2, and the ninth capacitor C9 are connected to the second output terminal To2. The resistance or the capacitance of at least at least any one or more of the resistive element, the capacitive elements, and the capacitor is varied. Such a feature successfully adjusts a phase of a signal to be output from the second output terminal To2.

The third resistive element R3, the third capacitive element C3, the fourth capacitive element C4, and the tenth capacitor C10 are connected to the third output terminal To3. The resistance or the capacitance of at least at least any one or more of the resistive element, the capacitive elements, and the capacitor is varied. Such a feature successfully adjusts a phase of a signal to be output from the third output terminal To3.

The fourth resistive element R4, the fifth capacitive element C5, the sixth capacitive element C6, and the eleventh capacitor C11 are connected to the fourth output terminal To4. The resistance or the capacitance of at least at least any one or more of the resistive element, the capacitive elements, and the capacitor is varied. Such a feature successfully adjusts a phase of a signal to be output from the fourth output terminal To4.

Here, the first capacitive element C1, the second capacitive element C2, and the ninth capacitor C9 are connected together at one end. The same applies to (a) the third capacitive element C3, the fourth capacitive element C4, and the tenth capacitor C10, (b) the fifth capacitive element C5, the sixth capacitive element C6, and the eleventh capacitor C11, and (c) the seventh capacitive element C7, the eighth capacitive element C8, and the twelfth capacitor C12. That is, in each of (a) to (c), the three capacitive elements (including the capacitor) are connected together at one end. As can be seen, when three capacitive elements are connected together at one end, the phase is adjusted in a wider range at an output terminal To in response to variations in frequency at an input terminal Ti. Described below will be how capacitive elements C connected together allow the phase to be adjusted in a wider range.

### Comparison Between Example and Comparative Example

Described below will be a comparison between characteristics of the poly-phase filter 10 according to an example corresponding to the first embodiment and characteristics of a poly-phase filter 10X according to a comparative example.

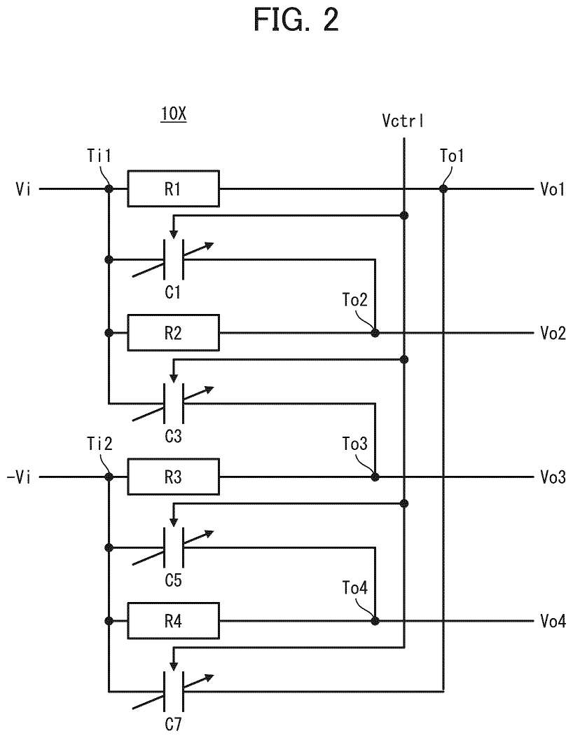

FIG. 2 illustrates a circuit diagram showing the poly-phase filter 10X according to a comparative example of the present invention. The poly-phase filter 10X omits the capacitive elements C2, C4, C6, C8, and C9 to C12, and the other ends of the capacitive elements C1, C3, C5, and C7 are directly and respectively connected to the output terminals To1, To2, To3, and To4. That is, the poly-phase filter 10X omits capacitive elements C connected together at one end. Note that, in the comparative example, capacitive elements are consistently denoted as the capacitive elements C1 to C12 for the sake of clarity.

If the capacitances of the first capacitive element C1 to the fourth capacitive element C4 are C and the resistances of the first resistive element R1 to the fourth resistive element R4 are R, the first output voltage Vo1 to the fourth output voltage Vo4 of the poly-phase filter 10X are represented as follows by transfer functions.

Vo1=−(CRs−1)Vi/(CRs+1).

Vo2=Vi.

Vo3=+(CRs−1)Vi/(CRs+1)=−Vo1.

Vo4=−Vi=−Vo2.

A phase difference θ between the first output voltage Vo1 and the second output voltage Vo2 is represented as follows.

Θ=Tan⁻¹[(2crω)/(1−C²R²ω²)].

As will be described below, the poly-phase filter 10 according to the first embodiment (hereinafter referred to as the example) has, for example, the capacitive elements C1, C2, and C9 connected together at one end. As a result, the poly-phase filter 10 can adjust a phase in a wider range in response to variations in input frequency than the poly-phase filter 10X according to the comparative example.

For the purpose of simplifying the evaluation, in the poly-phase filter 10X of the comparative example, the resistive elements R1 to R4 are assumed to have the same resistance R, and the capacitive elements C1, C3, C5, and C7 are assumed to have the same capacitance C. Here, a resonance frequency f of the capacitance C and the resistance R is represented by Equation (1) below.

f=1/(2πRC). Equation (1)

Here, if the capacitance C varies between Cₘᵢₙ and Cₘₐₓ (Cₘᵢₙ≤C≤Cₘₐₓ), a minimum value fₘᵢₙ and a maximum value fₘₐₓ of the resonance frequency f in the comparative example are represented by Equations (2a) and (2b) as follows (fₘᵢₙ≤f≤fₘₐₓ).

fₘᵢₙ=1/(2πRCₘₐₓ). Equation (2a)

fₘₐₓ=1/(2πRCₘᵢₙ). Equation (2b)

Here, a ratio F1 of the minimum value fₘᵢₙ to the maximum value fₘₐₓ of the resonance frequency f in the comparative example is represented by equation (3) as follows.

F1=fₘₐₓ/fₘᵢₙ=Cₘₐₓ/Cₘᵢₙ. Equation (3)

Whereas, also in the example, the capacitive elements C1 to C8 have the same capacitance 2C, and the resistive elements R1 to R4 have the resistance R. Furthermore, the capacitive elements C9 to C12 have the same capacitance Ca. Here, the resonance frequency f of two capacitances C, one capacitance Ca, and one resistance R is represented by Equation (4) below.

f=(Ca+4C)/(8πRC²). Equation (4)

Here, if the capacitance C varies between Cₘᵢₙ and Cₘₐₓ (Cₘᵢₙ≤C≤Cₘₐₓ), a minimum value fₘᵢₙ and a maximum value fₘₐₓ of the resonance frequency f in the example are represented by Equations (5a) and (5b) as follows (fₘᵢₙ≤f≤fₘₐₓ).

fₘᵢₙ=(Ca+4Cₘₐₓ)/(8πRCₘₐₓ²). Equation (5a)

fₘₐₓ=(Ca+4Cₘᵢₙ)/(8πRCₘᵢₙ²). Equation (5b)

Here, a ratio F2 of the minimum value fₘᵢₙ to the maximum value fₘₐₓ of the resonance frequency f in the example is represented by Equation (6) as follows.

F2=fₘₐₓ/fₘᵢₙ.

=(4Cₘₐₓ²Cₘᵢₙ+CaCₘₐₓ²)/[(4Cₘₐₓ+Ca)Cₘᵢₙ²]. Equation (6)

Here, a ratio F2 to F1 is represented by Equation 7 as follows.

F2/F1=(Cₘₐₓ(4Cₘᵢₙ+Ca))/[(4Cₘₐₓ+Ca)Cₘᵢₙ]. Equation (7)

A ratio α of Cₘₐₓ to Cₘᵢₙ and a ratio β of Ca to Cₘᵢₙ are defined as obtained by Equations (8).

α=Cₘₐₓ/Cₘᵢₙ, and β=Ca/Cₘᵢₙ, Equations (8)

where a relationship of α>1 and β≥0 holds.

When Equation (8) is applied to Equation (7), F2/F1 is represented by Equation (9) as follows.

F2/F1=α(4+β)/(4α+β)

=1+β(α−1)/(4α+β)≥1. Equation (9)

As can be seen, thanks to the capacitive elements C9 to C12 (the capacitance Ca), the frequency ratio F2 of the example is larger than the frequency ratio F1 of the comparative example, which shows that the example can handle a wider frequency range. Note that if the capacitance Ca of the capacitive elements C9 to C12 is 0, a relationship of β=1; that is, F2=F1, holds. This also shows that, thanks to the capacitive element C12 (the capacitance Ca), the example can handle a wider a frequency range.

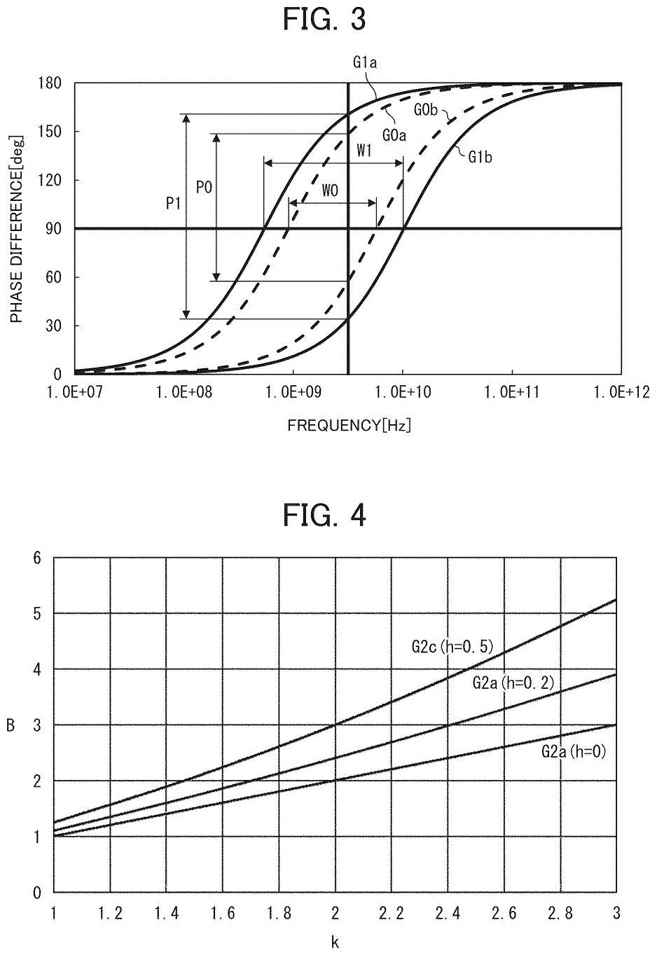

FIG. 3 shows a graph representing characteristics of poly-phase filters. In this graph, the horizontal axis represents frequency and the vertical axis represents phase difference. Graphs G1a and G1b show a range of a characteristic change in the example, and graphs G0a and G0b show a range of a characteristic change in the comparative example.

Here, the minimum value Cₘᵢₙ and the maximum value Cₘₐₓ of the capacitance C are defined as follows:
Cₘᵢₙ =12[fF]; and
Cₘₐₓ =77[fF].

Furthermore, the resistance R in the example is set to 5 kΩ. The capacitance Ca is set to 100 [fF]. The resistance R in the comparative example is set to 2.3 kΩ. The reason why the resistance values are different between the example and the comparative example is because the graphs of the example and the comparative example are overlaid with each other to facilitate understanding the difference in characteristic between the example and the comparative example.

As shown in FIG. 3, even if the example and the comparative example show the same ratio α of Cₘₐₓ to Cₘᵢₙ each representing a range in the capacitance change of the capacitive element C1, the example can achieve a phase difference of 90° in a wider frequency range. That is, as to a width W between frequencies with a phase difference of 90°, a width W1 in the example is greater than a width W0 in the comparative example. Furthermore, as to a variation width P between phase differences in the same frequency, a width P1 in the example is greater than a width P0 in the comparative example.

FIG. 4 shows a graph representing a relationship between capacitance ratios k and h and a frequency magnification B of a poly-phase filter.

The capacitance ratios k and h are variables defined by Equations (11a) and (11b) below.

k=Cₘₐₓ/C. Equation (11a)

h=Ca/Cₘₐₓ. Equation (11b)

C: A capacitance of the capacitive elements C1 to C8 (Cₘᵢₙ ≤C ≤Cₘₐₓ).

Cₘₐₓ: A maximum value of the capacitance C.

Cₘᵢₙ: A minimum value of the capacitance C.

### Ca: a Capacitance of the Capacitive Elements C9 to C12.

Here, in accordance with a range of the values that Equation (11a) and the capacitance C can have, a relationship of “k≥1” holds.

The frequency magnification B is defined by Equation (12) below.

B=F₉₀ /Fₘᵢₙ. Equation (12)
fₘᵢₙ: a minimum frequency with which a phase difference of 90° can be achieved when the capacitance Ca is 0 (where a relationship of the capacitance ratio h=0 and the capacitance ratio k=1 holds).
f₉₀: a frequency with which a phase difference of 90° can be achieved when the capacitance Ca is not 0.

The frequency f₉₀ can be obtained by Equation (13) below.

f₉₀=(2k+k²h)/(2πRCₘₐₓ). Equation (13)

Here, the numerical ranges of the capacitance ratios k and h are set as follows.
1≤k≤3,
h=0, 0.2, and 0.5.

As shown in FIG. 4, if the capacitance ratio k varies from 1 to 3 when the capacitance ratio holds h=0 (capacitance Ca=0), the frequency magnification B increases approximately threefold. Whereas, if the capacitance ratio holds h=0.2 and 0.5 (Ca=0.2*Cₘₐₓ, and 0.5*Cₘₐₓ), the frequency magnification B becomes greater. If the capacitance ratio holds h=0.5 (Ca=0.5*Cₘₐₓ), the frequency magnification B increases approximately fivefold.

Hence, the additional capacitive elements C9 to C12 (Ca≠0) can expand the frequency range in which a phase difference of 90° can be achieved. As can be seen, when such capacitive elements as C1, C2, and C9 are connected together at one end, the phase of an output voltage can be adjusted in a wide range in response to variations in input frequency.

### Modifications

Described below will be modifications of the first embodiment of the present invention. Note that, for convenience in description, like reference signs described in the above embodiment designate members having identical functions throughout the modifications. These members might not be elaborated upon repeatedly.

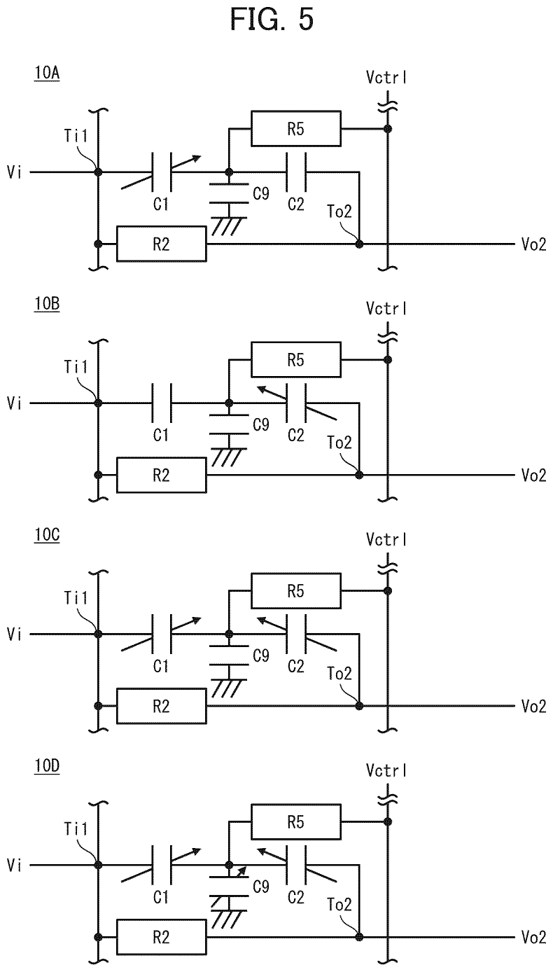

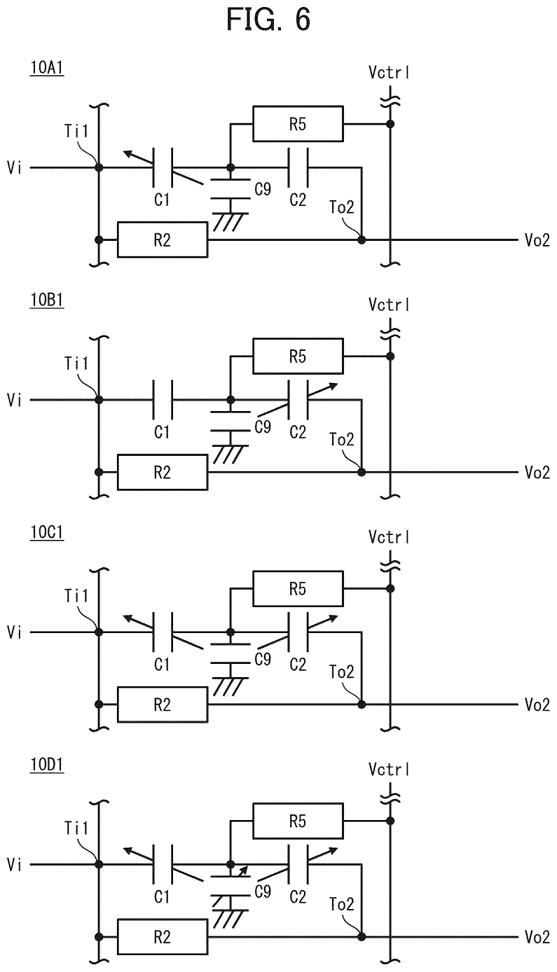

FIGS. 5 and 6 illustrate circuit diagrams showing poly-phase filters according to modifications of the first embodiment of the present invention.

Each of the circuit diagrams illustrates the first capacitive element C1, the second capacitive element C2, the ninth capacitor C9, and the second resistive element R2, all of which are connected to the second output terminal To2 and assumed to constitute a resonator. The same applies to the third output terminal To3, the fourth output terminal To4, and the first output terminal To1. For example, as to the first output terminal To1, the seventh capacitive element C7, the eighth capacitive element C8, and the twelfth capacitor C12 and the first resistive element R1 constitute a resonator.

As to a poly-phase filter 10A, the capacitance of the first capacitive element C1 alone is variable. As to a poly-phase filter 10B, the capacitance of the second capacitive element C2 alone is variable, As to a poly-phase filter 10C, the capacitances of both the first capacitive element C1 and the second capacitive element C2 are variable. As to a poly-phase filter 10D, the capacitances of all the first capacitive element C1, the second capacitive element C2, and the ninth capacitor C9 are variable. Note that even though the poly-phase filter 10C is substantially the same as the poly-phase filter 10, the poly-phase filter 10C is illustrated to facilitate comparison with poly-phase filters 10A1 to 10D1 in FIG. 6.

Here, the capacitance of the capacitive element C is varied with a varactor diode. The first capacitive element C1, the second capacitive element C2, and the ninth capacitor C9 are connected together at one end to the positive electrode of the varactor diode.

Similar to the poly-phase filters 10A to 10D, as to the poly-phase filter 10A1, the capacitance of the first capacitive element C1 alone is variable. As to the poly-phase filter 10B1, the capacitance of the second capacitive element C2 alone is variable, As to the poly-phase filter 10C1, the capacitances of both the first capacitive element C1 and the second capacitive element C2 are variable. As to the poly-phase filter 10D1, the capacitances of all the first capacitive element C1, the second capacitive element C2, and the ninth capacitor C9 are variable.

Also as to each of the poly-phase filters 10A1 to 10D1, the capacitance of the capacitive element is varied with a varactor diode. Note that, basically, the first capacitive element C1, the second capacitive element C2, and the ninth capacitor C9 are connected together at one end to the negative electrode of the varactor diode.

Note that, in the poly-phase filter 10D1, as to the ninth capacitor C9 of the poly-phase filter 10D1, the one ends are connected together to the positive electrode of the varactor diode. The orientation of the ninth capacitor C9 (the varactor diode) may be reversed.

Hence, as seen in FIGS. 5 and 6, when the orientation of the varactor diode is changed, the poly-phase filters could have different characteristics caused by, for example, a difference in ground capacitance at each of the positive electrode and the negative electrode of the varactor diode. That is, the varactor diode can be configured in accordance with the orientation of the varactor diode.

As described above, the capacitance of at least any one or more of the first capacitive element C1, the second capacitive element C2, and the ninth capacitor C9 is set variable, so that a phase of the second output terminal To2 can be adjusted. In addition, the resistance of the second resistance element R2 may be set variable, so that the phase of the second output terminal To2 may be adjusted. Furthermore, as to the third output terminal To3, the fourth output terminal To4, and the first output terminal To1, the capacitance and the resistance of the capacitive element C and the resistive element R constituting a resonator may be variable. Hence, the conditions below can be derived.

At least one of: (1a) a capacitance of at least any one or more of the seventh capacitive element C7, the eighth capacitive element C8, and the twelfth capacitor C12; or (1b) a resistance of the first resistive element R1 may be variable. Such a feature successfully adjusts a phase of a signal to be output from the first output terminal To1.

At least one of: (2a) a capacitance of at least any one or more of the first capacitive element C1, the second capacitive element C2, and the ninth capacitor C9; or (2b) a resistance of the second resistive element R2 may be variable. Such a feature successfully adjusts a phase of a signal to be output from the second output terminal To2.

At least one of: (3a) a capacitance of at least any one or more of the third capacitive element C3, the fourth capacitive element C4, and the tenth capacitor C10; or (3b) a resistance of the third resistive element R3 may be variable. Such a feature successfully adjusts a phase of a signal to be output from the third output terminal To3.

At least one of: (4a) a capacitance of at least any one or more of the fifth capacitive element C5, the sixth capacitive element C6, and the eleventh capacitor C11; or (4b) a resistance of the fourth resistive element R4 may be variable. Such a feature successfully adjusts a phase of a signal to be output from the fourth output terminal To4.

### Second Embodiment

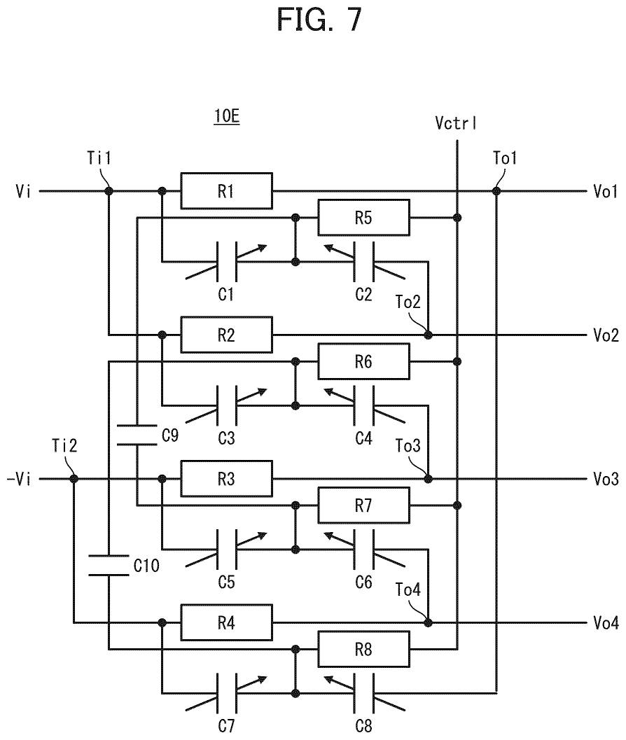

Described below will be another embodiment of the present invention, with reference to FIG. 7. Note that, for convenience in description, like reference signs described in the above embodiment designate members having identical functions throughout the second embodiment. These members might not be elaborated upon repeatedly.

The second embodiment is similar to the first embodiment 1 in many respects. Described below will be how the second embodiment is different from the first embodiment.

First, the second embodiment omits the eleventh capacitor C11 and the twelfth capacitor C12.

Furthermore, the other end of the ninth capacitor C9 is connected to the other end of the fifth capacitive element C5, and the other end of the tenth capacitor C10 is connected to the other end of the seventh capacitive element C7. That is, the ninth capacitor C9 has: an end connected to an other end of the first capacitive element C1; and an other end connected to an other end of the fifth capacitive element C5. The tenth capacitor C10 has: an end connected to an other end of the third capacitive element C3; and an other end connected to an other end of the seventh capacitive element C7. As a result, the ninth capacitor C9 serves to adjust a phase between the second output terminal To2 and the fourth output terminal To4, and the tenth capacitor C10 serves to adjust a phase between the third output terminal To3 and the first output terminal To1.

Here, capacitances of the ninth capacitor C9 and the tenth capacitor C10 are fixed. Whereas, the capacitance of at least one of the ninth capacitor C9 or the tenth capacitor C10 may be variable.

At least one of: (1c) a capacitance of at least any one or more of the seventh capacitive element C7 and the eighth capacitive element C8; or (1b) a resistance of the first resistive element R1 may be variable. Such a feature successfully adjusts a phase of a signal to be output from the first output terminal To1. Note that, here, the capacitances of the seventh capacitive element C7 and the eighth capacitive element C8 are variable, and the resistance of the first resistive element R1 is fixed.

At least one of: (4c) a capacitance of at least any one or more of the fifth capacitive element C5 and the sixth capacitive element C6; or (4b) a resistance of the fourth resistive element R4 may be variable. Such a feature successfully adjusts a phase of a signal to be output from the fourth output terminal To4. Note that, here, the capacitances of the fifth capacitive element C5 and the sixth capacitive element C6 are variable, and the resistance of the fourth resistive element R4 is fixed.

Otherwise, the second embodiment is not substantially different from the first embodiment, and thus detailed descriptions of the second embodiment will be omitted.

### SUMMARY

A poly-phase filter according to a first aspect of the present invention includes:
a first resistive element having an end connected to a first input terminal and an other end connected to a first output terminal;
a second resistive element having an end connected to the first input terminal and an other end connected to a second output terminal;
a first capacitive element having an end connected to the first input terminal;
a second capacitive element having an end connected to an other end of the first capacitive element and an other end connected to the second output terminal;
a third resistive element having an end connected to a second input terminal and an other end connected to a third output terminal;
a third capacitive element having an end connected to the second input terminal;
a fourth capacitive element having an end connected to an other end of the third capacitive element and an other end connected to the third output terminal;
a fourth resistive element having an end connected to the second input terminal and an other end connected to a fourth output terminal;
a fifth capacitive element having an end connected to the second input terminal;
a sixth capacitive element having an end connected to an other end of the fifth capacitive element and an other end connected to the fourth output terminal;
a seventh capacitive element having an end connected to the second input terminal;
an eighth capacitive element having an end connected to an other end of the seventh capacitive element and an other end connected to the first output terminal;
a ninth capacitor having an end connected to the other end of the first capacitive element;
a tenth capacitor having an end connected to the other end of the third capacitive element;
an eleventh capacitor having an end connected to the other end of the fifth capacitive element; and
a twelfth capacitor having an end connected to the other end of the seventh capacitive element,
wherein at least one of: (1a) a capacitance of at least any one or more of the seventh capacitive element, the eighth capacitive element, and the twelfth capacitor; or (1b) a resistance of the first resistive element is variable,
at least one of: (2a) a capacitance of at least any one or more of the first capacitive element, the second capacitive element, and the ninth capacitor; or (2b) a resistance of the second resistive element is variable,
at least one of: (3a) a capacitance of at least any one or more of the third capacitive element, the fourth capacitive element, and the tenth capacitor; or (3b) a resistance of the third resistive element is variable, and
at least one of: (4a) a capacitance of at least any one or more of the fifth capacitive element, the sixth capacitive element, and the eleventh capacitor; or (4b) a resistance of the fourth resistive element is variable.

Thanks to the above features, the first capacitive element, the second capacitive element, and the ninth capacitor are connected together at one end. Furthermore, (a) the third capacitive element, the fourth capacitive element, and the tenth capacitor are connected together at one end, (b) the fifth capacitive element, the sixth capacitive element, and the eleventh capacitor are connected together at one end, and (c) the seventh capacitive element, the eighth capacitive element, and the twelfth capacitor are connected together at one end. As can be seen, when three capacitive elements are connected together at one end, the phase is adjusted in a wider range at an output terminal To in response to variations in frequency at an input terminal Ti.

As to the poly-phase filter of a second aspect of the present invention according to the first aspect, other ends of the ninth capacitor, the tenth capacitor, the eleventh capacitor, and the twelfth capacitor may be connected to a ground.

Such a feature successfully stabilizes resonators each having a corresponding one of the ninth capacitor C9 to the twelfth capacitor C12.

A poly-phase filter according to a third aspect of the present invention includes:
a first resistive element having an end connected to a first input terminal and an other end connected to a first output terminal;
a second resistive element having an end connected to the first input terminal and an other end connected to a second output terminal;
a first capacitive element having an end connected to the first input terminal;
a second capacitive element having an end connected to an other end of the first capacitive element and an other end connected to the second output terminal;
a third resistive element having an end connected to a second input terminal and an other end connected to a third output terminal;
a third capacitive element having an end connected to the first input terminal;
a fourth capacitive element having an end connected to an other end of the third capacitive element and an other end connected to the third output terminal;
a fourth resistive element having an end connected to the second input terminal and an other end connected to a fourth output terminal;
a fifth capacitive element having an end connected to the second input terminal;
a sixth capacitive element having an end connected to an other end of the fifth capacitive element and an other end connected to the fourth output terminal;
a seventh capacitive element having an end connected to the second input terminal;
an eighth capacitive element having an end connected to an other end of the seventh capacitive element and an other end connected to the first output terminal;
a ninth capacitor having an end connected to the other end of the first capacitive element and an other end connected to the other end of the fifth capacitive element; and
a tenth capacitor having an end connected to the other end of the third capacitive element and an other end connected to the other end of the seventh capacitive element,
wherein at least one of: (1c) a capacitance of at least any one or more of the seventh capacitive element and the eighth capacitive element; or (1b) a resistance of the first resistive element is variable,
at least one of: (2a) a capacitance of at least any one or more of the first capacitive element, the second capacitive element, and the ninth capacitor; or (2b) a resistance of the second resistive element is variable,
at least one of: (3a) a capacitance of at least any one or more of the third capacitive element, the fourth capacitive element, and the tenth capacitor; or (3b) a resistance of the third resistive element is variable, and
at least one of: (4c) a capacitance of at least any one or more of the fifth capacitive element and the sixth capacitive element; or (4b) a resistance of the fourth resistive element is variable.

Thanks to the above features, the first capacitive element, the second capacitive element, and the ninth capacitor are connected together at one end. Furthermore, (a) the third capacitive element, the fourth capacitive element, and the tenth capacitor are connected together at one end, (b) the fifth capacitive element, the sixth capacitive element, and the eleventh capacitor are connected together at one end, and (c) the seventh capacitive element, the eighth capacitive element, and the twelfth capacitor are connected together at one end. As can be seen, when three capacitors are connected together at one end, the phase is adjusted in a wider range at an output terminal To in response to variations in frequency at an input terminal Ti. Note that the ninth capacitor C9 serves to adjust a phase between the second output terminal and the fourth output terminal, and the tenth capacitor C10 serves to adjust a phase between the third output terminal and the first output terminal.

As to the poly-phase filter of a fourth aspect of the present invention according to any one of the first to third aspects, at least any one or more of the first capacitive element to the eighth capacitive element, the ninth capacitor, and the tenth capacitor may be varactor diodes capacitances of which are variable.

The above feature successfully facilitates variations in the capacitance of at least any one or more of the first capacitive element to the eighth capacitive element, the ninth capacitor, and the tenth capacitor. Furthermore, an orientation of the varactor diode is appropriately determined, so that various characteristics are readily exhibited.

An electronic appliance according to a fifth aspect of the present invention includes the poly-phase filter according to any one of the first to fourth aspects.

The above feature readily allows an electronic appliance to handle a wide range of frequencies.

The present invention shall not be limited to the embodiments described above, and can be modified in various manners within the scope of claims. The technical aspects disclosed in different embodiments are to be appropriately combined together to implement another embodiment. Such an embodiment shall be included within the technical scope of the present invention. Furthermore, the technical aspects disclosed in each embodiment may be combined to achieve a new technical feature.

While there have been described what are at present considered to be certain embodiments of the invention, it will be understood that various modifications may be made thereto, and it is intended that the appended claim cover all such modifications as fall within the true spirit and scope of the invention.

What is claimed is:

1. A poly-phase filter, comprising:
a first resistive element having an end connected to a first input terminal and an other end connected to a first output terminal;
a second resistive element having an end connected to the first input terminal and an other end connected to a second output terminal;
a first capacitive element having an end connected to the first input terminal;
a second capacitive element having an end connected to an other end of the first capacitive element and an other end connected to the second output terminal;
a third resistive element having an end connected to a second input terminal and an other end connected to a third output terminal;
a third capacitive element having an end connected to the first input terminal;
a fourth capacitive element having an end connected to an other end of the third capacitive element and an other end connected to the third output terminal;
a fourth resistive element having an end connected to the second input terminal and an other end connected to a fourth output terminal;
a fifth capacitive element having an end connected to the second input terminal;
a sixth capacitive element having an end connected to an other end of the fifth capacitive element and an other end connected to the fourth output terminal;
a seventh capacitive element having an end connected to the second input terminal;
an eighth capacitive element having an end connected to an other end of the seventh capacitive element and an other end connected to the first output terminal;
a ninth capacitor having an end connected to the other end of the first capacitive element;
a tenth capacitor having an end connected to the other end of the third capacitive element;
an eleventh capacitor having an end connected to the other end of the fifth capacitive element; and
a twelfth capacitor having an end connected to the other end of the seventh capacitive element,
wherein at least one of: (1a) a capacitance of at least any one or more of the seventh capacitive element, the eighth capacitive element, and the twelfth capacitor; or (1b) a resistance of the first resistive element is variable,
at least one of: (2a) a capacitance of at least any one or more of the first capacitive element, the second capacitive element, and the ninth capacitor; or (2b) a resistance of the second resistive element is variable,
at least one of: (3a) a capacitance of at least any one or more of the third capacitive element, the fourth capacitive element, and the tenth capacitor; or (3b) a resistance of the third resistive element is variable, and
at least one of: (4a) a capacitance of at least any one or more of the fifth capacitive element, the sixth capacitive element, and the eleventh capacitor; or (4b) a resistance of the fourth resistive element is variable.

2. The poly-phase filter according to claim 1,
wherein other ends of the ninth capacitor, the tenth capacitor, the eleventh capacitor, and the twelfth capacitor are connected to a ground.

3. A poly-phase filter, comprising:
a first resistive element having an end connected to a first input terminal and an other end connected to a first output terminal;
a second resistive element having an end connected to the first input terminal and an other end connected to a second output terminal;
a first capacitive element having an end connected to the first input terminal;
a second capacitive element having an end connected to an other end of the first capacitive element and an other end connected to the second output terminal;
a third resistive element having an end connected to a second input terminal and an other end connected to a third output terminal;
a third capacitive element having an end connected to the first input terminal;
a fourth capacitive element having an end connected to an other end of the third capacitive element and an other end connected to the third output terminal;
a fourth resistive element having an end connected to the second input terminal and an other end connected to a fourth output terminal;
a fifth capacitive element having an end connected to the second input terminal;
a sixth capacitive element having an end connected to an other end of the fifth capacitive element and an other end connected to the fourth output terminal;
a seventh capacitive element having an end connected to the second input terminal;
an eighth capacitive element having an end connected to an other end of the seventh capacitive element and an other end connected to the first output terminal;
a ninth capacitor having an end connected to the other end of the first capacitive element and an other end connected to the other end of the fifth capacitive element; and
a tenth capacitor having an end connected to the other end of the third capacitive element and an other end connected to the other end of the seventh capacitive element,
wherein at least one of: (1c) a capacitance of at least any one or more of the seventh capacitive element and the eighth capacitive element; or (1b) a resistance of the first resistive element is variable,
at least one of: (2a) a capacitance of at least any one or more of the first capacitive element, the second capacitive element, and the ninth capacitor; or (2b) a resistance of the second resistive element is variable,
at least one of: (3a) a capacitance of at least any one or more of the third capacitive element, the fourth capacitive element, and the tenth capacitor; or (3b) a resistance of the third resistive element is variable, and
at least one of: (4c) a capacitance of at least any one or more of the fifth capacitive element and the sixth capacitive element; or (4b) a resistance of the fourth resistive element is variable.

4. The poly-phase filter according to claim 1,
wherein at least any one or more of the first capacitive element to the eighth capacitive element, the ninth capacitor, and the tenth capacitor are varactor diodes capacitances of which are variable.

5. An electronic appliance comprising the poly-phase filter according to claim 1.

6. The poly-phase filter according to claim 3,
wherein at least any one or more of the first capacitive element to the eighth capacitive element, the ninth capacitor, and the tenth capacitor are varactor diodes capacitances of which are variable.

7. An electronic appliance comprising the poly-phase filter according to claim 3.
